(19) United States
(12) Patent Application Publication
(10) Pub. No.: US 2025/0004720 A1
(43) Pub. Date: Jan. 2, 2025

(54) HYBRID MATRIX MULTIPLIER

(71) Applicant: SYNTHARA AG, Zurich (CH)

(72) Inventors: Avinash GUTTA, Bengaluru (IN); Vijayagopalan Manu NAIR, Zurich (CH)

(21) Appl. No.: 18/707,588

(22) PCT Filed: Nov. 25, 2021
(86) PCT No.: PCT/IB2021/060992

§ 371 Date: May 5, 2024

(30) Foreign Application Priority Data
Nov. 10, 2021 (EP) 21207400.9

(51) Int. Cl. G06F 7/544; G06F 7/50; G06F 7/523; H03K 19/20

(52) U.S. Cl. CPC G06F 7/5443; G06F 7/50; G06F 7/523; H03K 19/20

(57) ABSTRACT

A hybrid multiply-accumulate circuit includes an array of single-bit multiply-accumulate circuits. Each single-bit multiply accumulate circuit has a first storage element for storing a first single-bit value, a second storage element for storing a second single-bit value, a multiply circuit for multiplying the first single-bit value times the second single-bit value to calculate a product, and an analog storage circuit. The multiply circuit is operable to deposit a charge in the analog storage circuit representative of the product. The analog storage circuits are together operable to combine the charges deposited in each analog storage circuit to provide an accumulated charge representative of a sum of the products. A hybrid matrix multiplier includes an array of hybrid multiply-accumulate circuits and an adder operable to add the accumulated values to produce a matrix value. The matrix value and the adder can be digital or analog.

### TECHNICAL FIELD

The present disclosure relates generally to processing architectures, devices, and methods for matrix multiplication and, in particular to hybrid multiply-accumulate circuits.

### BACKGROUND

Matrix multiplication is an important operation in many mathematical computations. For example, linear algebra can employ matrix multiplication to solves systems of linear equations such as differential equations. Such mathematical computations are applied, for example, in pattern matching, artificial intelligence, analytic geometry, engineering, physics, natural sciences, computer science, computer animation, and economics.

Matrix multiplication is typically performed in digital computers executing stored programs. The programs describe the operations to be performed and hardware in the computer, for example digital multipliers and adders perform the operations. In some computing systems, specially designed hardware can accelerate the rate of computation. In some applications, real-time processing is necessary to provide useful output in useful amounts of time, especially for safety-critical tasks. Moreover, applications in portable devices have only limited power available. Despite such accelerated computing systems, problems with large matrices and high data rates can take longer to solve and use more power than desired. There is a need therefore, for computing hardware accelerators that can perform matrix multiplication at higher rates and with less power.

### SUMMARY

Embodiments of the present disclosure can provide, inter alia, hybrid computing hardware accelerators for performing matrix multiplication using multiply accumulate operations. Computing hardware accelerators of the present disclosure comprises digital binary single-bit multipliers with an analog accumulator. The data values for the single-bit multipliers are each stored in a digital memory and the single-bit multiplication results are stored as a charge in a capacitor. The capacitor charges are combined to sum (accumulate) the values and thus provide a multiply-accumulate operation. By combining capacitor charges, the summation operation is nearly instantaneous, relying on the rate at which charges in a conductor can flow and requiring no external power. Thus, embodiments of the present disclosure can provide a very high speed and low power multiply-accumulate circuit. Because charge is notated as Q in electronic systems, each single-bit multiply-accumulate circuit is referred to as a qmac herein and is a hybrid circuit using digital multiplication and analog accumulation.

According to embodiments of the present disclosure, a hybrid multiply-accumulate circuit comprises an array of single-bit multiply-accumulate circuits, each single-bit multiply accumulate circuit comprising (i) a first storage element for storing a first single-bit value, (ii) a second storage element for storing a second single-bit value, (iii) a bit-multiply circuit for multiplying the first single-bit value times the second single-bit value to calculate a product, and (iv) an analog storage circuit, wherein the bit-multiply circuit is operable to deposit a charge in the analog storage circuit representative of the product. The array of single-bit multiply-accumulate circuits are together operable to combine the charges deposited in each analog storage circuit to provide an accumulated charge representative of a sum of the products. The analog storage circuit can be a capacitor.

According to some embodiments, the hybrid multiply-accumulate circuit comprises a switch circuit connected to the bit-multiply circuit and to the analog storage circuit operable in a first mode to transfer charge from the bit-multiply circuit to the analog storage circuit and operable in a second mode to isolate the bit-multiply circuit from the analog storage circuit and connect the analog storage circuits in the array together to provide the accumulated charge. Some embodiments comprise a clear circuit connected to the analog storage circuits of the array operable remove charge from the analog storage circuits in the array. In some embodiments, the bit-multiply circuit is a functional AND gate or performs the function of an AND gate.

In some embodiments of the present disclosure, the hybrid multiply-accumulate circuit comprises an analog-to-digital converter to convert the accumulated charge connected to the analog storage circuits in the array to a digital accumulated value. Some embodiments comprise a shift circuit or a shift electrical connection to multiply the digital accumulated value by a power of two. Some embodiments comprise a digital adder operable to add the digital accumulated values to produce a digital matrix value. The digital adder can be pipelined

In some embodiments an analog-to-digital converter to convert the output of the analog storage circuits 16 of the parallel-connected qmacs 10 is not present and the addition of the output of the array of hybrid multiply-accumulate circuits is performed by an analog adder operable to add the accumulated charges to produce an analog matrix value. Some embodiments comprise a voltage multiplier connected to the analog storage circuits in the array to multiply the accumulated charges by a power of two. Such an addition and multiplication can be performed by an operational amplifier configured as an adder with op amp inputs connected to the analog storage circuits operable to provide the analog matrix value. The op amp inputs of the operational amplifier can be configured to multiply or divide the op amp inputs by a power of two. Some embodiments comprise an analog-to digital converter to convert the analog matrix value to produce a digital matrix value, so that the output of the op amp is digitized.

In some embodiments, the bit-multiply circuit comprises serially connected switches, for example serial switch circuits comprising pairs of MOS transistors, a first MOS transistor controlled by a positive control signal and a second MOS transistors controlled by an inverted (negative) version of the same control signal. One of the serially connected switches can be controlled by a weight value and another by an input value representing a matrix multiplication of weight values and input values.

According to embodiments of the present disclosure, a hybrid matrix multiplier comprises digital storage elements, each of the digital storage elements operable to store a digital value, a multiply circuit for multiplying the stored digital values to produce a product, and an analog storage circuit operable to store the product. A voltage connection can provide power to operate the digital storage elements, the multiply circuit, and the analog storage circuit. In some embodiments, a power connection provides power to operate the digital storage elements, the multiply circuit, and the analog storage circuit and has a voltage no greater than one V (e.g., no greater 500 mV, no greater than 100 mV, no greater than 50 mV, or no greater than 10 mV). The multiply circuit can comprises serially connected switches comprising pairs of MOS transistors.

Embodiments of the present disclosure provide fast, efficient, low-power, and small hybrid hardware accelerators that perform matrix multiplication using multiply accumulate operations.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIGS. 1A and 1B mathematically illustrate matrix multiplication operations useful in understanding embodiments of the present disclosure;

FIGS. 1C and 1D illustrate matrix multiplication operations with simplified computer-programs useful in understanding embodiments of the present disclosure;

FIG. 2 is a functional schematic of a single-bit multiply-accumulate circuit according to illustrative embodiments of the present disclosure;

FIG. 3 is a schematic of a one-dimensional array of single-bit multiply accumulate circuits shown in FIG. 2 according to illustrative embodiments of the present disclosure;

FIG. 4A is a functional schematic of a single-bit multiply-accumulate circuit with a switch circuit and a clear circuit according to illustrative embodiments of the present disclosure;

FIG. 4B is an abstraction of the functional schematic of FIG. 4A according to illustrative embodiments of the present disclosure;

FIG. 4C is a timing diagram for operating the single-bit multiply-accumulate circuit of FIG. 4A according to illustrative embodiments of the present disclosure;

FIG. 5 is a schematic of a one-dimensional array of single-bit multiply accumulate circuits shown in FIG. 4A according to illustrative embodiments of the present disclosure;

FIG. 6 graphically illustrates a multiplication operation with multiply-accumulate values useful in understanding embodiments of the present disclosure;

FIG. 7 is a schematic of a two-dimensional array of single-bit multiply-accumulate circuits with a digital summation circuit according to illustrative embodiments of the present disclosure;

FIG. 8 is a schematic of a two-dimensional array of single-bit multiply-accumulate circuits with an analog summation circuit according to illustrative embodiments of the present disclosure;

FIGS. 9-10 are schematics of analog summation circuits according to illustrative embodiments of the present disclosure;

FIG. 11A is a schematic of a vector matrix hybrid multiply-accumulate circuit and FIG. 11B illustrates the matrix values in the vector matrix hybrid multiply-accumulate circuit of FIG. 11A according to illustrative embodiments of the present disclosure;

FIG. 12 is a schematic of a vector matrix hybrid multiply-accumulate circuit comprising a two-dimensional array of single-bit multiply-accumulate circuits with an analog summation circuit as shown in FIG. 8 according to illustrative embodiments of the present disclosure;

FIG. 13 is an abstract schematic of cascaded switches controlled with analog voltages demonstrating low-power single-bit multiplication according to illustrative embodiments of the present disclosure; and

FIG. 14 is a schematic of a switch controlled with low-power analog voltages according to illustrative embodiments of the present disclosure.

The features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not necessarily drawn to scale.

### DETAILED DESCRIPTION OF CERTAIN EMBODIMENTS

Certain embodiments of the present disclosure are directed towards single-bit hybrid multiply-accumulate circuits (each a qmac) comprising two digital single-bit binary storage elements that each store a single-bit value, a multiplier to multiply the two single-bit values to compute a product, and an analog charge storage element, such as a capacitor, for storing the product as a charge (or voltage). One dimensional arrays of qmacs can compute and sum a one-dimensional array (a vector) of single-bit products. Two dimensional arrays of qmacs can compute a product for two multi-bit digital multiplicands. (A multiplicand is a value to be multiplied by another to calculate a multiplied product.) The size of the two-dimensional array of qmacs for computing a multi-bit multiplicand can be N+M−1 where N is the number of bits in one of the two digital multiplicands and M is the number of bits in the other of the two digital multiplicands. A vector matrix multiplication and accumulation for two linear vectors (one-dimensional arrays of numbers) with M values can be computed with M two-dimensional arrays and accumulated as a single value.

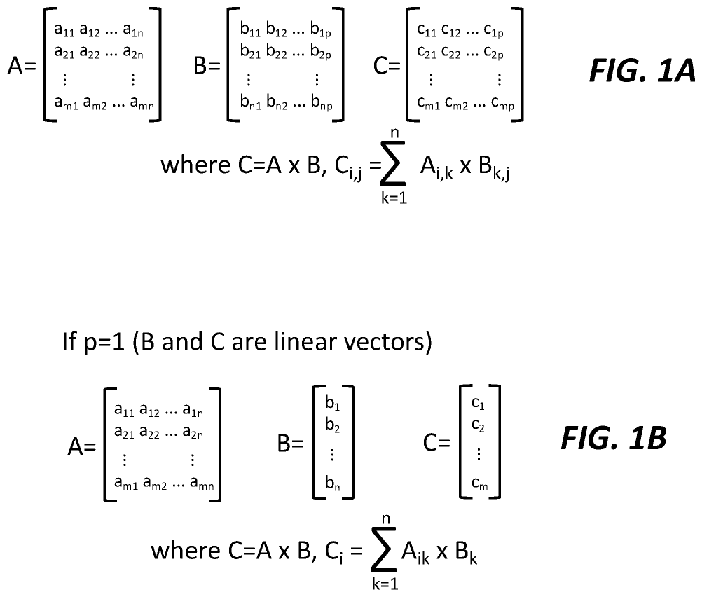

As shown in FIG. 1A, the computation C=A×B where A, B, and C are matrices is a matrix multiplication. If A is an m×n matrix, B is an n×p matrix, then C is an m×p matrix where Cᵢⱼ=ΣAᵢₖ Bₖⱼ for k=1 to n, i=1 to m, and j=1 to p. The summation operation for products of A and B for k=1 to N is a multiply-accumulate (mac) operation. Thus, a matrix multiplication is a series of (i×j) multiply-accumulate operations of size k, each multiply-accumulate operation providing one value of matrix C. FIG. 1B illustrates the computation C=A×B where p=1 so that C and B are linear (e.g. one dimensional or vector) matrices. FIG. 1C is a simplified software program illustrating the computation of the matrix computation of FIG. 1A and FIG. 1D is a simplified software program illustrating the computation of the matrix computation of FIG. 1D. The “For k=0 to (n−1)” loop is a multiply-accumulate operation requiring n multiplications and n additions.

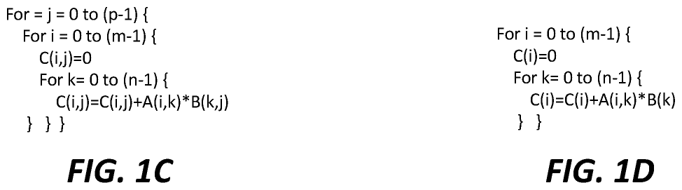

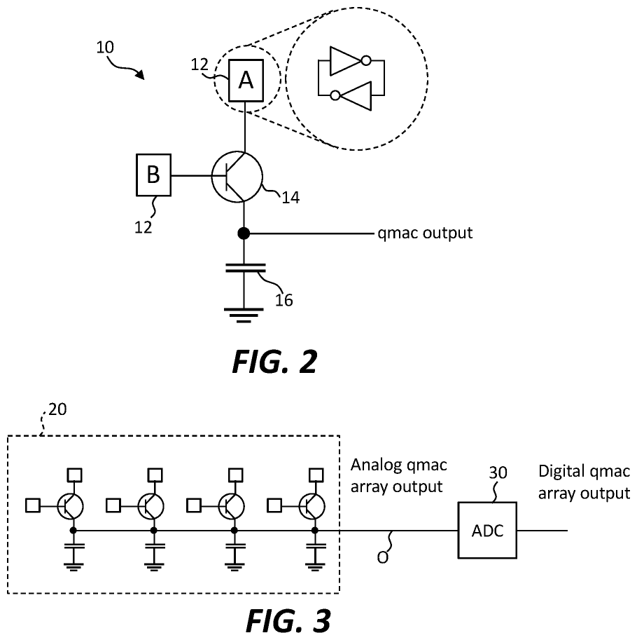

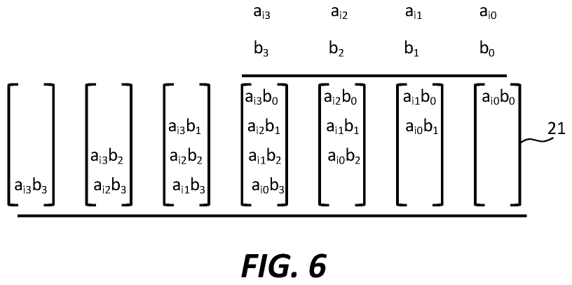

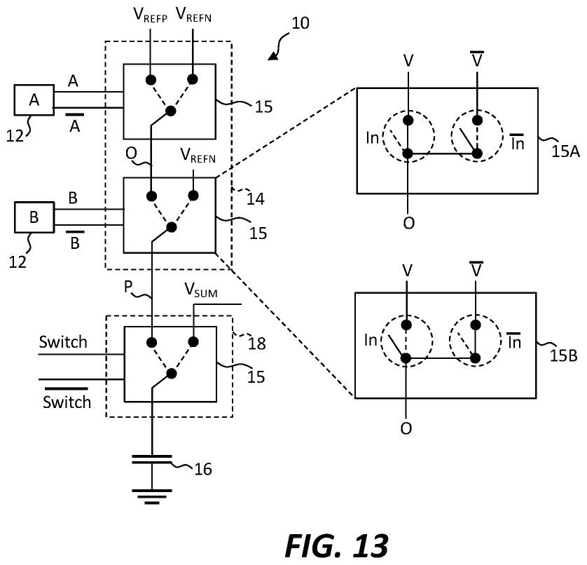

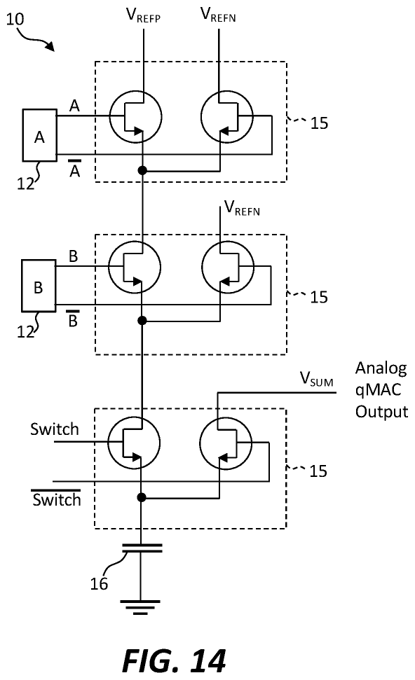

According to embodiments of the present disclosure and as shown in FIGS. 2 and 3, a hybrid multiply-accumulate operation can be performed by an array of qmacs 10, where each qmac 10 comprises a first digital, single-bit binary storage element 12 for storing a first bit A, a second digital, single-bit binary storage element 12 for storing a second bit B, a bit multiplier 14 (a bit-multiply circuit 14) for multiplying multiplicands A and B, producing a product that is stored as a charge in bit capacitor 16 (analog storage circuit 16). In some embodiments storage element 12 is an SRAM cell, a DRAM cell, a flip-flop (e.g., a D flip-flop), or a pair of invertors connected with input to output, as shown in the FIG. 2 inset. In some embodiments, bit multiplier 14 is an AND gate providing a positive value (e.g., one) only when both A and B are positive (e.g., one), thus providing a multiplication. AND gates, as shown in FIG. 2, can be implemented as a transistor with a source connected to the storage element 12 for A and a gate connected to the storage element 12 for B (or vice versa) that provides charge Q stored in bit capacitor 16 when the product of multiplicands A and B is a one value. If a value of A or B is the same for different qmacs 10, the storage element 12 for the constant can be shared by multiple qmacs 10 (e.g., a single storage element 12 can provide an input value to multiple qmacs 10, as shown in FIG. 7 discussed below). As will be appreciated by those knowledgeable in analog and digital circuit design, FIGS. 2 and 3 are simplified designs and much more complex designs are included as embodiments of the present disclosure, such as those illustrated in FIGS. 13 and 14 discussed below that can operate at very low voltages and power. For example, the amount of current deposited on bit capacitor 16 can be very small to reduce the power used by qmac 10 and increase the circuit speed. Bit capacitor 16 can be very small, to reduce the area of bit capacitor 16 in an integrated circuit embodiment. Thus, in some embodiments, bit multiplier 14 very precisely controls the current depositing charge on bit capacitor 16 over time to maintain the accuracy and precision of the multiply-accumulate operation. Thus, bit multiplier 14 can be designed to very precisely control the amount of charge deposited on bit capacitor 16, for example responsive to a carefully calibrated timing signal and voltage.

FIG. 3 illustrates four qmacs 10 with bit capacitors 16 (analog storage circuits 16) connected in parallel to sum the four products in a hybrid multiply-accumulate circuit 20. The four parallel qmacs 10 provide a multiply accumulate operation for four single-bit A values each multiplied by a single-bit B value. The single-bit B values can be the same, or different. Thus, FIG. 3 illustrates a circuit for performing a multiply accumulate operation for four single-bit, binary values (e.g., where k=4 in the mathematical illustration of FIGS. 1A-1D). Thus, the array of single-bit multiply-accumulate circuits 10 are together operable to combine the charges deposited in each analog storage circuit 16 to provide an accumulated charge representative of a sum of the products of the qmacs 10.

The total charge on the parallel-connected bit capacitors 16 provide an analog accumulated value output O that can be converted to a digital value with an analog-to-digital converter (ADC) 30 or used as an analog value for further computations. The absolute value of the voltage or charge (output O) must be scaled by the number of capacitors n because the parallel capacitors have a capacitance equal to the sum of the capacitance of the parallel-connected capacitors. Since the charge on a capacitor is equal to the voltage times the capacitance (Q-CV), if the capacitance increases for a fixed charge the voltage will correspondingly decrease. For example, if every capacitor stores a charge Q equivalent to a one value, the sum of the values will be four (in the illustration of FIG. 3) but the voltage will remain one because the four capacitors are electrically connected in parallel. Thus, the voltage output must be scaled by the number of capacitors (e.g., a factor of four in the illustration of FIG. 3).

Hybrid multiply-accumulate circuits can require less power than a digital equivalent, e.g., using digital adders. The net current or charge leakage from small bit capacitors 16 can be very small and the analog storage circuits 16 and other analog operations can operate at a very low voltage, for example no greater than 1 volt (e.g., no greater than 500 mV, no greater than 100 mV, no greater than 50 mV, or no greater than 10 mV) and lower than a voltage used for conventional digital logic (e.g., 5V, 3.6 V, 3.3 V, or 1.65 V). Some embodiments of the present disclosure can operate at substantially 10 mV.

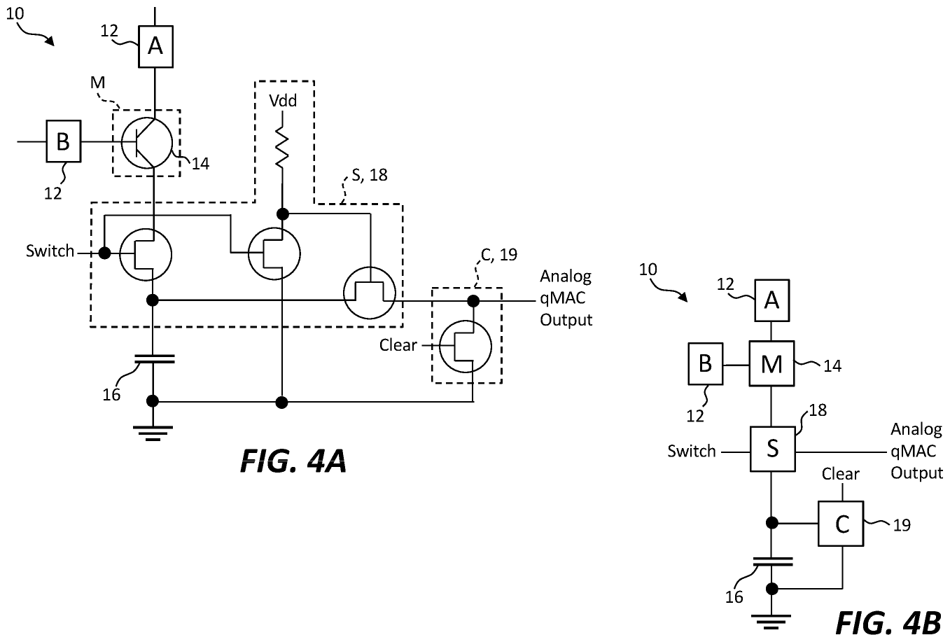

The FIGS. 2 and 3 circuits are a simplified representation of qmacs 10 and their implementation in a multiply-accumulate array. As noted, precise control of charge deposition on bit capacitors 16 helps to maintain multiply-accumulate accuracy and precision. As illustrated in FIG. 4A, a more complex circuit for a qmac 10 controls the electrical connection between qmacs 10 in an array of qmacs 10 with a switch circuit 18 (also designated as S in the figures) connected to the output of bit multiplier 14 and to bit capacitor 16. When switch circuit 18 is on, charge Q representing the product of bits A and B is deposited on bit capacitor 16 through the left transistor of switch circuit 18. When switch circuit 18 is off, the left transistor is turned off, an inverter comprising the center transistor in switch circuit 18 applies a positive signal to a connection switch comprising the right transistor of switch circuit 18, connecting bit capacitors 16 in parallel.

Switch circuit 18 of FIG. 4A is a simplified circuit and more complex circuits can be implemented to provide the switch function and are included in the present disclosure. Thus, in a first mode, switch circuit 18 is on and the product of the multiplication by bit multiplier 14 is separately and individually applied to transfer charge to bit capacitor 16 in each qmac 10. In a second mode, switch circuit 18 is off, bit capacitors 16 are connected in parallel and the charges Q on bit capacitors 16 in each qmac 10 are isolated from bit multiplier 14 and are summed to provide the accumulated value output O. A clear circuit 19 (also designated as C in the figures) connected across bit capacitor 16 can remove charge Q across bit capacitors 16 and prepare qmac 10 to perform a next multiplication with new single-bit digital values A and B. FIG. 4B shows an abstraction of the single-bit multiply-accumulate circuit 10 of FIG. 4A where A and B are the single-bit digital storage elements 12, M is bit multiplier 14, S is switch circuit 18, and C is clear circuit 19.

FIG. 4C illustrates a multiply-accumulate cycle for a qmac 10. Load signals A and B are set to store the corresponding values in storage elements 12, for example provided by a computer or other state machine controller and are multiplied by bit multiplier 14. At the same time, the clear signal is high and the switch signal is low to isolate and clear bit capacitor 16. Once bit capacitor 16 is cleared, the clear signal is set low and the switch signal can be set high to deposit charge Q representing the product of A and B in bit capacitor 16. Once charge Q is loaded into bit capacitor 16, the switch signal is set low to isolate bit multiplier 14 from bit capacitor 16 and to connect all of bit capacitors 16 in parallel, thereby summing charges Q on bit capacitors 16 to provide accumulated value output O. The summed charges Q equal to output O, properly scaled, can be converted to a digital value with an analog-to-digital converter 30 or used for further computation as an analog value. The entire operation can be done in two cycles as switch circuit 18 changes from the first mode to the second mode.

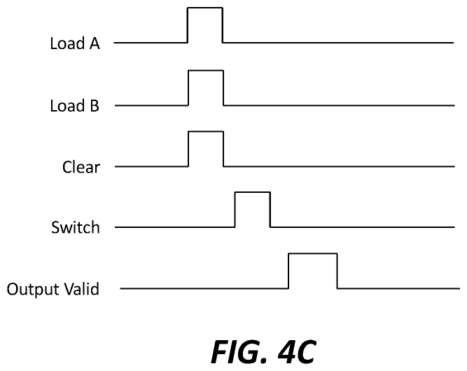

FIG. 5 illustrates an array of qmacs 10 forming hybrid multiply-accumulate circuit 20 using the abstract representation of FIG. 4B. In some embodiments, a single clear circuit 19 can be used to clear charge from all of bit capacitors 16 connected when switch circuit 18 is off, but switch circuits 18 connected between bit capacitors 16 can interfere with charge removal for all of bit capacitors 16. In some embodiments clear circuit 19 is provided for each qmac 10 and clear circuits 19 are controlled in common, as are switch circuit 18, in hybrid multiply-accumulate circuit 20.

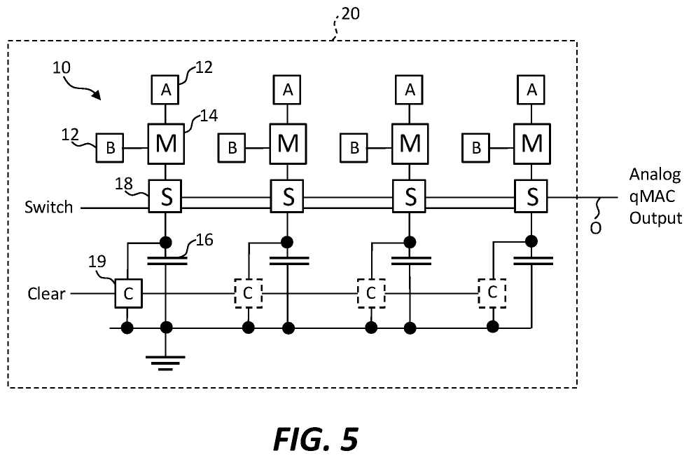

FIG. 6 illustrates a complete multiplication for two binary, multi-digit, multi-bit values. FIG. 6 illustrates a case with values having four bits, but any number of bits can be used for a hybrid multiply-accumulate circuit 20 having a number of qmacs 10 corresponding to the number of bits multiplied. The number of qmacs 10 in each hybrid multiply-accumulate circuit 20 corresponds to the number of bits in A and the number of hybrid multiply-accumulate circuits 20 corresponds to the number of multiply-accumulate calculations to be done at the same time. Where the number of qmacs 10 is less than the number of bits in A or the number of multiply-accumulate calculations to be done at the same time is less than the number of bits in B, partial calculations can be performed and the products stored and combined under the control of an external computer or controller such as a state machine.

As shown in the 4-bit example of FIG. 6, each row of products shown is a multiplication of one bit of value B times the bits of value A. The rows are spatially shifted with respect to each other in FIG. 6 to represent the relative magnitude (place) of the products in each row as is conventional for multiplication written manually on paper. The products (multiplied values) of each column 21 of products (having the same magnitude or place) are summed in each hybrid multiply-accumulate circuit 20 to form an accumulated result (summation output value O) as shown in FIG. 5. Each column 21 of products can be computed and summed with a different hybrid multiply-accumulate circuit 20. The accumulated results (output value O) of the hybrid multiply-accumulate circuits 20 are then summed (added together) to provide a final value of the multi-bit multiplication.

The multiplication and accumulation of each column 21 of products can be performed by a one-dimensional array of qmacs 10. As shown in FIG. 7, each column of qmacs 10 forms a hybrid multiply-accumulate circuit 20 sharing a common B storage element 12. The array of qmacs 10 in each hybrid multiply-accumulate circuit 20 (in this example corresponding to the multiplication illustrated in FIG. 6) calculates and sums a column 21 of products as output value O. Each column 21 of products is computed with a separate hybrid multiply-accumulate circuit 20. The output values O of each hybrid multiply-accumulate circuit 20 can be added together. Because each column 21 of products has a different place value (relative magnitude) the values in each column 21 of products must be scaled to multiply them by their place value, e.g., by one to 6 places to multiply them by 2, 4, 8, 16, 32, or 64, before they are added. Multiple multiplication operations can be performed without reloading the bit values (B storage elements 12) where the bits do not change, for example if the bit values represent weights that are common to multiplying multiple input values.

The array of hybrid multiply-accumulate circuit 20 forming a hybrid multi-bit multiplier 22 provides extremely fast operation having far fewer cycles than conventional digital circuits. Furthermore, the addition steps for summing the output values O (if done digitally) can be divided into stages (e.g., adding pairs of values at a time) and pipelined so that operation is even faster and multiply-accumulate operations for different values can be overlapped in time, for example under the control of a computer or state-machine controller.

In some embodiments of the present disclosure, the addition of output values O from the hybrid multiply-accumulate circuits 20 are calculated digitally. In some embodiments, the addition of output values O from the hybrid multiply-accumulate circuits 20 are calculated using analog circuits. As shown in FIG. 7, the output values) are converted with analog-to-digital converters 30 to provide digital bit values stored, for example, in a register or other memory, the digital bit values are scaled, for example by shifting them relative to each other (each shift corresponding to a power of two), and the scaled bit values summed using a digital adder.

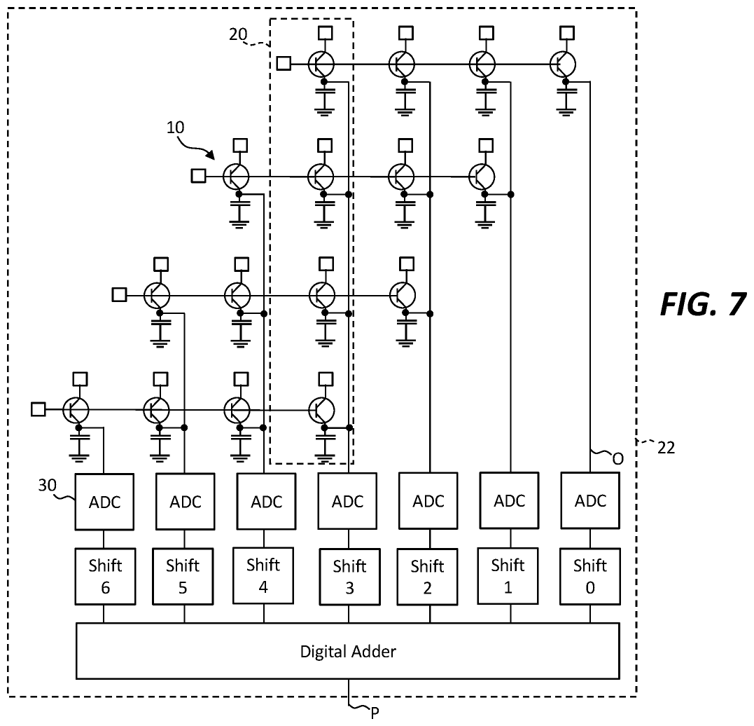

As shown in FIG. 8, the analog summation result of each hybrid multiply-accumulate operation (column of qmacs 10) is a voltage (or charge) that is multiplied by an amount corresponding to the place of the analog sum (e.g., by a voltage multiplier VM) and the multiplied analog sums are added together, for example using an analog adder, and the final summation converted to a digital value with an analog-to-digital converter 30. In such embodiments, the entire calculation can be done in two switch cycles (excluding any clear or load cycles) providing very fast operation compared to conventional implementations. FIG. 8 illustrates embodiments with separate storage elements 12 for each qmac 10.

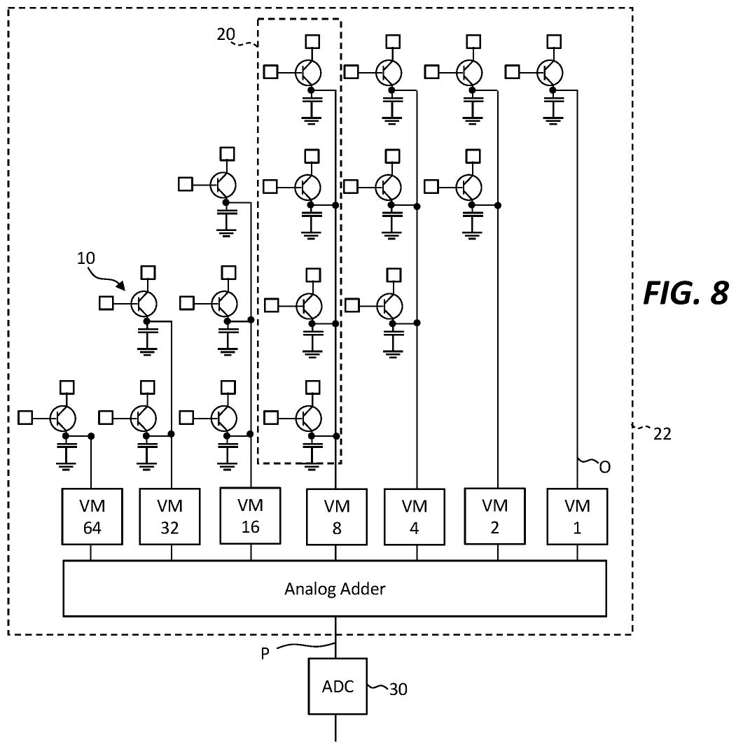

The analog voltage multiplication and summation can be, in some embodiments, implemented using operational amplifiers (op amps) 40 configured in a summation mode. FIG. 9 illustrates an inverting summing (adding) operational amplifier 40. The output Vo of the op amp 40 is equal to the sum of each of the voltages V₁ to V_{N} times the ratio of R′/Rₙ where n is the specific column and N is the number of columns 21 of products to be added (e.g., seven in the example of FIG. 7). Each voltage corresponds to the output O of a column of qmacs 10. For example, R1 can correspond to the lowest place value to be summed so R′/R₁=1/64, R′/R₂=1/32, R′/R₃=1/16, R′/R₄=1/8, R′/R₅=1/4, R′/R₆=1/1, and R′/R₇=1. The inverted output of op amp 40 can be converted to a digital value using an analog-to-digital converter 30 and scaled appropriately.

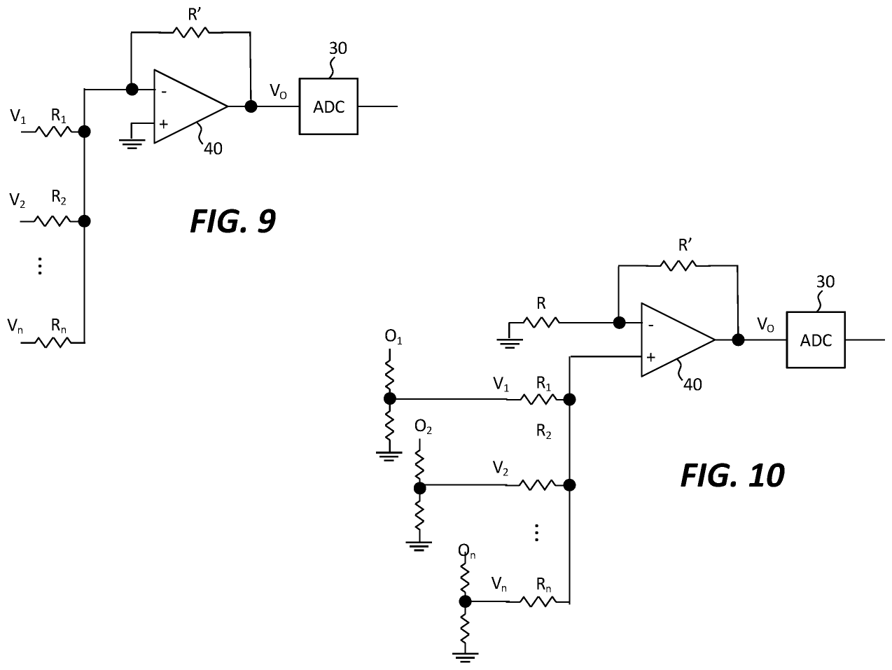

FIG. 10 illustrates a non-inverting summing (adding) operational amplifier 40. The output Vo of the op amp 40 is equal to the sum of each of the voltages V₁ to V_{N} times the ratio of R′/R where R₁-R_{N} are each equal. The voltage values V1-VN can be scaled with a voltage divider implemented with resistors. For example, the resistors connected to V₁ can have a ratio of 63:1, the resistors connected to V₂ can have a ratio of 31:1, the resistors connected to V₃ can have a ratio of 15:1, and so forth top scale the voltages to correspond to the place of the value added. The output of the op amp 40 can be scaled by the ratio of (R+R′)/R (for example 64) and converted to a digital value using an analog-to-digital converter 30.

The embodiments of FIGS. 7 and 8 with analog summing can provide faster operation and the embodiments of FIG. 6 with digital summing can provide greater precision. Embodiments of the present disclosure are not limited by the number of bits illustrated. For example, a hybrid multiply accumulator circuit 20 can have 64, 128, 256, 512, 1024, 2048, 4096, 8192, or 16384 qmacs 10 or more, and an equal number of a hybrid multiply-accumulate circuits 20 can be employed in an array to provide high-speed multiplication with many bits. Embodiments of the present disclosure can be provided as a hardware accelerator to a conventional computer or graphic processor. Data can be supplied to the hardware accelerator in a pipeline fashion with a two or more shift registers on the input and output. Any hardware implementation of an array of hybrid multiply-accumulate circuits 20 must be sized to efficiently accommodate the sizes of the input vectors. If the array of hybrid multiply-accumulate circuits 20 is too large for the task, much of the circuit is not used (e.g., the number of qmacs 10 is too large). If the array of hybrid multiply-accumulate circuits 20 is too small, the vector multiplication must be broken down into smaller vectors; too many small vectors likewise lead to inefficiency.

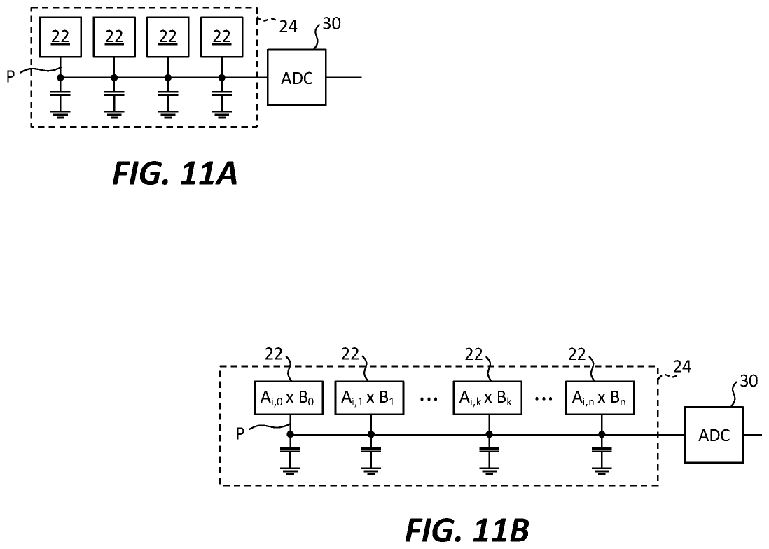

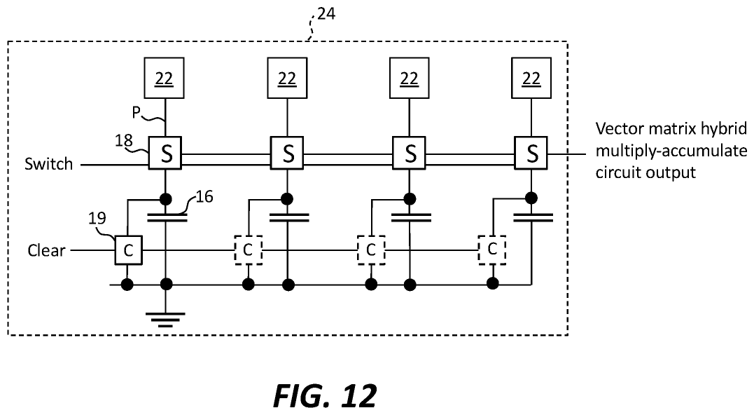

As shown in FIG. 6, a two-dimensional multiplication array of single-bit multiply-accumulate circuits 10 can perform a multi-bit multiplication (e.g., as shown in FIGS. 7 and 8). A hybrid multi-bit multiplier 22 comprising multiple arrays such as those of FIGS. 8 and 9, forming a hybrid matrix multiply-accumulate circuit 24 can compute an entire vector multiplication. Each multi-bit multiplication for a vector multiply-accumulate (e.g., as shown in FIG. 1B) can produce a digital product (as shown in FIG. 7 or after analog-to-digital conversion of analog sum output value O) and the digital products can be added digitally using digital adders. In some embodiments, each multi-bit multiplication for a vector multiply-accumulate (e.g., as shown in FIG. 1B) can produce an analog product (output value O as shown in FIG. 8) and the analog products can be added using a similar circuit as is shown in FIGS. 1-6. The analog product P (shown in FIG. 8) can be deposited in a capacitor (e.g., similar to bit-capacitor 16 but greater storage capacity for larger charges) using deposition circuitry similar to that of bit multiplier 14. As shown in FIG. 12 switch and clear circuits 18, 19 similar to those of FIG. 5 can deposit charge Q on the capacitors and the charges can be summed by connecting the capacitors in parallel and then converting the summed charge with an analog-to-digital converter 30 to provide an entire vector matrix multiplication in one cycle. FIG. 11A illustrates the hybrid matrix multiply-accumulate circuit 24 and FIG. 11B associates the hybrid multi-bit multiplier 22 with the multiplicands in the vector multiply-accumulate calculation.

Embodiments of the present disclosure can provide very low-voltage multiply accumulate circuits 10, for example using a voltage from 10 mV to 1 V. Such a low voltage provides low-power operation. A bit-multiplier 14 using a conventional AND gate can require, for example, six relatively large transistors operating at a relatively high voltage to implement a bit-multiply circuit that can adequately control the charge Q deposited on analog storage circuit 16 (e.g., from 1.65-5 V). In contrast and as shown in FIG. 13, bit-multipliers 14 of the present disclosure can comprise serially connected serial switch circuits 15 that can operate at relatively low voltages (e.g., no greater than 1 V and as low as 10 mV) and low power and can adequately control the charge Q deposited on analog storage circuit 16 with, for example, only four relatively small transistors.

As shown in FIG. 13, a series of three serial switch circuits 15 and analog storage circuit 16 can implement a qmac 10 functionally similar to the circuits illustrated in FIGS. 4A and 4B. Each serial switch circuit 15 has two differential voltage inputs (V and V with a bar, where Vbar is the inverted value of V), two voltage inputs In and In with a bar, where Inbar is the inverted value of In), and an output O. Thus, each of the signals A, B, and Switch in FIG. 13 and FIG. 14 (discussed in more detail below) is a differential signal. The first serial switch circuit 15 in the series has a reference voltage V_{REFP} (e.g., V_{REF}, a high or positive value such as 10 mV) and its inverted value V_{REFN} (e.g., a low or negative values such as 0 mV) as the two voltage inputs and a value A (e.g., a weight value) and its inverted value Abar as the two input values. As shown in the FIG. 13 inset of serial switch circuit 15A, if A is high (e.g., positive or 10 mV) and Abar is consequently low (e.g., 0 mV), the output O is V_{REF}, as indicated by the non-dashed line connections. As shown in the FIG. 13 inset of serial switch circuit 15B, if A is low (e.g., negative or 0 mV) and Abar is consequently high (e.g., 10 mV), output O is V_{REFN}, as indicated by the non-dashed lines Thus, if A is positive, O is positive and if A is negative, O is negative. The second serial switch 15 in the series has input values B and its inversion Bbar, takes value O from the first serial switch 15 as the V_{REFP} positive value, and V_{REFN} as the inverted voltage value (e.g., 0 volts). Thus, if O is low (negative), no matter what value B has, the output P from the second serial switch circuit 15 will be low (negative). If O is high (positive) and if B is high (positive), the output O from the second serial switch circuit 15 will be high (positive), and if B is low the output P from the second serial switch circuit 15 will be low (negative). Thus, the first two serial switch circuits 15 perform an AND function with reduced circuitry and power.

A third serial switch circuit 15 can be used to implement the switch circuit 18 and has input switch values and its inversion (corresponding to the switch value of FIGS. 4A, 4B), takes value O from the second serial switch 15 as the V_{REF} value, and a common V_{SUM} connection as the inverted voltage value. Thus, if the switch is high, output O charges analog storage circuit 16. If the switch is low, the charge Q on analog storage circuit 16 is commonly connected to any other analog storage circuit 16 in an array of qmacs 10 (e.g., as shown in FIG. 3 as the analog qmac 10 array output), providing a sum operation.

FIG. 14 illustrates some embodiments of a low-voltage qmac 10 comprising three serially connected serial switch circuits 15. Each switch circuit 15 comprises a pair of simple MOS (metal-oxide semiconductor) transistors having separate differential inputs and a common output. One of the pair of simple MOS transistors is controlled by a positive control signal and the other by an inverted (negative) version of the same control signal, for example the positive and negative outputs of any single-bit storage element 12 (e.g., a D-flipflop or pairs of inverters as illustrated and described with respect to FIG. 2). The function of the circuit is as described above with respect to FIG. 13. Such a series of serial switch circuits 15 can require fewer, simpler transistors that operate at a much lower voltage (e.g., one percent or less than one percent, such as 0.624 percent, or 10 mV instead of 1.65 volts) and therefore require much less power. The combined (added) voltage on analog storage circuits 16 can be:

$${V}_{SUM} = ( ( n * {V}_{REFP} ) + ( N - n ) * {V}_{REFN} ) ) / N .$$

$$Where {V}_{REFN} = 0 volts :$$

$${V}_{SUM} = ( n * {V}_{REFP} ) / N ,$$

where n is the number of capacitors and N the number of qmacs 10 connected in a row. VSUM can then be scaled or converted as described above. (FIG. 14 does not include a clear circuit 19.)

Thus, according to some embodiments of the present disclosure, a hybrid matrix multiplier comprises digital storage elements 12, each of digital storage elements 12 operable to store a digital value, a multiply circuit 14 for multiplying the stored digital values to produce a product, an analog storage circuit 16 operable to store the product, and a power connection (e.g., V_{REFP} and V_{REFN}) for providing power to operate digital storage elements 12, multiply circuit 14, and analog storage circuit 16. The power connection can have a voltage no greater than one V, no greater 500 mV, no greater than 100 mV, no greater than 50 mV, or no greater than 10 mV. The bit-multiply circuit 14 can comprise serially connected switches 15.

In some embodiments, a hardware implementation of hybrid matrix multiply-accumulate circuit 24, hybrid multi-bit multiplier 22, or hybrid multiply-accumulate circuit 20 is not exactly matched to the calculation desired for a specific application. For such applications, the calculation can be divided into sub-problems that are better matched to the available hardware and the results combined to provide the desired computation. The sub-problems can be done sequentially in time so that the hardware is time-shared or time multiplexed. Some of the values (for example the bits for multiplicand B) can be stored in storage elements 12 for multiple hardware operations, thereby reducing power and time used in the hardware.

Embodiments of the present disclosure enable vector multiply-accumulate calculations using very little energy at very high rates. Rather requiring n loops of a program (e.g., as shown in FIGS. 1C and 1D), each with multiple machine code cycles required to execute the program, the entire calculation is done in a single cycle. Many large matrix operations, for example in machine learning applications, have many zero values in the matrix and a relatively lower bit precision is required to iterate a solution to a matching problem. Thus, embodiments of the present disclosure provide an efficient circuit for such applications.

Embodiments of the present disclosure are not limited to the specific examples illustrated in the figures and described herein. Skilled designers will readily appreciate that various implementations of analog and digital circuits can be employed to implement the operations described and such implementations are included in embodiments of the present disclosure.

Embodiments of the present disclosure can be used in neural networks, pattern-matching computers, or machine-learning computers and provide efficient and timely processing with reduced power and hardware requirements. Such embodiments can comprise a computing accelerator, e.g., a neural network accelerator, a pattern-matching accelerator, a machine learning accelerator, or an artificial intelligence computation accelerator designed for static or dynamic processing workloads.

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific elements, or where processes and methods are described as having, including, or comprising specific steps, it is contemplated that, additionally, there are apparatus and systems of the disclosed technology that consist essentially of, or consist of, the recited elements, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The disclosure has been described in detail with particular reference to certain embodiments thereof, but it will be understood that variations and modifications can be effected within the spirit and scope of the following claims.

### PARTS LIST

c clear circuit
M multiplier circuit/multiplier
O output value
S switch/switch circuit
VM voltage multiplier
10 qmac/single-bit multiply-accumulate circuit
12 single-bit storage element
14 bit multiplier/bit-multiply circuit
15, 15A, 15B serial switch circuit
16 capacitor/analog storage circuit
18 switch/switch circuit
19 clear/clear circuit
20 hybrid multiply-accumulate circuit
21 column of products
22 hybrid multi-bit multiplier
24 hybrid matrix multiply-accumulate circuit
30 analog-to-digital converter
40 operational amplifier/op amp

1. A hybrid multiply-accumulate circuit, comprising:
an array of single-bit multiply-accumulate circuits, each single-bit multiply-accumulate circuit comprising (i) a first storage element for storing a first single-bit value, (ii) a second storage element for storing a second single-bit value, (iii) a bit-multiply circuit for multiplying the first single-bit value times the second single-bit value to calculate a product, and (iv) an analog storage circuit, wherein the bit-multiply circuit is operable to deposit a charge in the analog storage circuit representative of the product,
wherein the array of single-bit multiply-accumulate circuits are together operable to combine the charges deposited in each analog storage circuit to provide an accumulated charge representative of a sum of the products,
wherein each of the single-bit multiply-accumulate circuits comprises serially connected switch circuits comprising pairs of MOS transistors, and
wherein the MOS transistors (i) have differential signal inputs and (ii) have differential voltage inputs.

2. The hybrid multiply-accumulate circuit of claim 1, wherein the analog storage circuit is a capacitor.

3. The hybrid multiply-accumulate circuit of claim 1, comprising a switch circuit connected to the bit-multiply circuit and to the analog storage circuit operable in a first mode to transfer charge from the bit-multiply circuit to the analog storage circuit and operable in a second mode to isolate the bit-multiply circuit from the analog storage circuit and connect the analog storage circuits in the array together to provide the accumulated charge.

4. The hybrid multiply-accumulate circuit of claim 1, comprising a clear circuit connected to the analog storage circuits of the array operable to remove charge from the analog storage circuits in the array.

5. The hybrid multiply-accumulate circuit of claim 4, wherein each single-bit multiply accumulate circuit comprises a clear circuit connected to the analog storage circuit operable to remove charge from the analog storage circuit.

6. The hybrid multiply-accumulate circuit of claim 1, wherein the bit-multiply circuit is a functional AND gate.

7. The hybrid multiply-accumulate circuit of claim 1, comprising an analog-to-digital converter to convert the accumulated charge connected to the analog storage circuits in the array to a digital accumulated value.

8. The hybrid multiply-accumulate circuit of claim 7, comprising a shift circuit or a shift electrical connection to multiply the digital accumulated value by a power of two.

9. The hybrid multiply-accumulate circuit of claim 1, comprising a voltage multiplier connected to the analog storage circuits in the array to multiply the accumulated charge by a power of two.

10. The hybrid multiply-accumulate circuit of claim 1, comprising (i) a first storage element for storing a first value, (ii) a second storage element for storing a second value, (iii) a multiply circuit for multiplying the first value times the second value to calculate a product, and (iv) an analog storage circuit.

11. The hybrid multiply-accumulate circuit of claim 10, wherein the first and second values are binary, single-bit digital values and the multiply circuit is operable to deposit a charge in the analog storage circuit representative of the product.

12. The hybrid multiply-accumulate circuit of claim 1, wherein the bit-multiply circuit comprises serially connected switches.

13. The hybrid multiply-accumulate circuit of claim 1, wherein the MOS transistors are operable at a voltage lower than a voltage used for digital logic.

14. The hybrid multiply-accumulate circuit of claim 13, wherein the voltage lower than a voltage used for digital logic is no greater than 1 V, no greater than 0.5 volts, no greater than 0.1 volts, no greater than 0.05 volts, or no greater than 0.01 volts.

15. A hybrid matrix multiplier, comprising an array of hybrid multiply-accumulate circuits of claim 7 and a digital adder operable to add the digital accumulated values to produce a digital matrix value.

16. The hybrid matrix multiplier of claim 15, wherein the digital adder is pipelined.

17. A hybrid matrix multiplier, comprising an array of hybrid multiply-accumulate circuits of claim 1 and an analog adder operable to add the accumulated charge to produce an analog matrix value.

18. The hybrid matrix multiplier of claim 17, comprising an operational amplifier configured as an adder with op amp inputs connected to the analog storage circuits operable to provide the analog matrix value.

19. The hybrid matrix multiplier of claim 18, wherein the op amp inputs of the operational amplifier are configured to multiply or divide the op amp inputs by a power of two.

20. The hybrid matrix multiplier of claim 17, comprising an analog-to-digital converter to convert the analog matrix value to produce a digital matrix value.

21. The hybrid matrix multiplier of claim 1, wherein each of the single-bit multiply-accumulate circuits comprises three serially connected switch circuits comprising pairs of MOS transistors, each pair of MOS transistors having separate inputs and a common output.

22. The hybrid matrix multiplier of claim 21, wherein the serially connected switch circuits comprise:
(i) a first serial switch circuit connected to a reference voltage and its inverted reference value, the first serial switch circuit controlled by the first single-bit value and its inverted value as the separate inputs, providing output O;
(ii) a second serial switch circuit connected to output O of the first serial switch circuit and the inverted reference value, the second serial switch circuit controlled by the second single-bit value and its inverted value as the separate inputs, providing output O; and
(iii) a third serial switch circuit connected to output O of the second serial switch and a common sum voltage as the inverted voltage value, the third switch circuit controlled by a switch and its inverted value, the output of the third switch circuit connected to the analog storage circuit.

23. A hybrid matrix multiplier, comprising:
digital storage elements, each of the digital storage elements operable to store a digital value;
a multiply circuit for multiplying the stored digital values to produce a product, wherein the multiply circuit comprises serially connected switch circuits;
an analog storage circuit operable to store the product; and
a power connection for providing power to operate the digital storage elements, the multiply circuit, and the analog storage circuit, the power connection having a voltage no greater than one V (e.g., no greater than 500 mV, no greater than 100 mV, no greater than 50 mV, or no greater than 10 mV) and lower than a voltage used for digital logic.

24. The hybrid matrix multiplier of claim 23, wherein the serially connected switches comprise pairs of MOS transistors and wherein the MOS transistors (i) have differential signal inputs and (ii) have differential voltage inputs.
